(19) United States
(12) Patent Application Publication
(10) Pub. No.: US 2012/0043866 A1
(43) Pub. Date: Feb. 23, 2012

(54) ADJUSTABLE APPARATUS FOR ELECTRONIC DEVICE

(75) Inventors: KUN-CHI HSIEH, Tu-Cheng (TW); LI TONG, Shenzhen City (CN); JUN-ZHI XU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/964,256

(22) Filed: Dec. 9, 2010

(30) Foreign Application Priority Data
Aug. 17, 2010 (CN) 201010255360.8

(51) Int. Cl. H05K 5/02

(52) U.S. Cl. 312/223.1

(57) ABSTRACT

An adjustable apparatus includes an enclosure for securing a display, a support located on a ground, a hinge secured to the support and a mounting member. A hole is defined in the enclosure. The mounting member includes a main body and a pivot piece connected to the main body. The main body of the mounting member is attached to an inside of the enclosure, and the pivot piece passes through the enclosure through the hole and rotatably engages with the hinge.

### BACKGROUND

1. Technical Field

The present disclosure relates to adjustable apparatuses, and particularly to a adjustable apparatus for an electronic device.

2. Description of Related Art

A conventional adjustable apparatus is usually secured to the back of a display device by screws. When the viewing angle of the display device needs to be adjusted, it is necessary to remove the screws, which is very inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an adjustable apparatus and an enclosure in accordance with an embodiment.

FIG. 2 is an exploded, isometric view of the adjustable apparatus in accordance with an embodiment.

FIG. 3 an assembled view of FIG. 2, showing in a different aspect.

FIG. 4 is a partially assembled view of FIG. 1.

FIG. 5 is an assembled view of FIG. 1, showing in a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

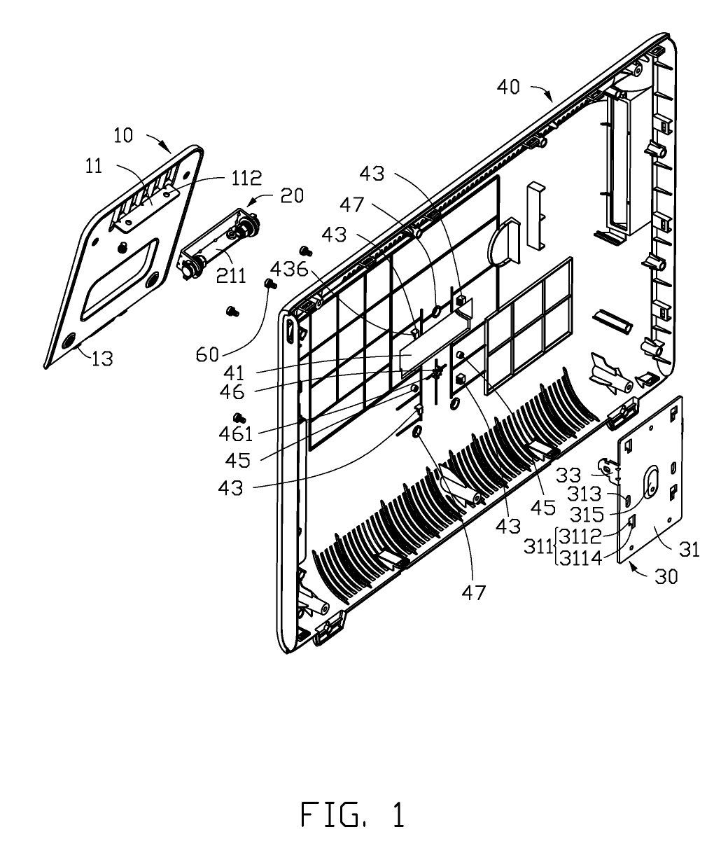

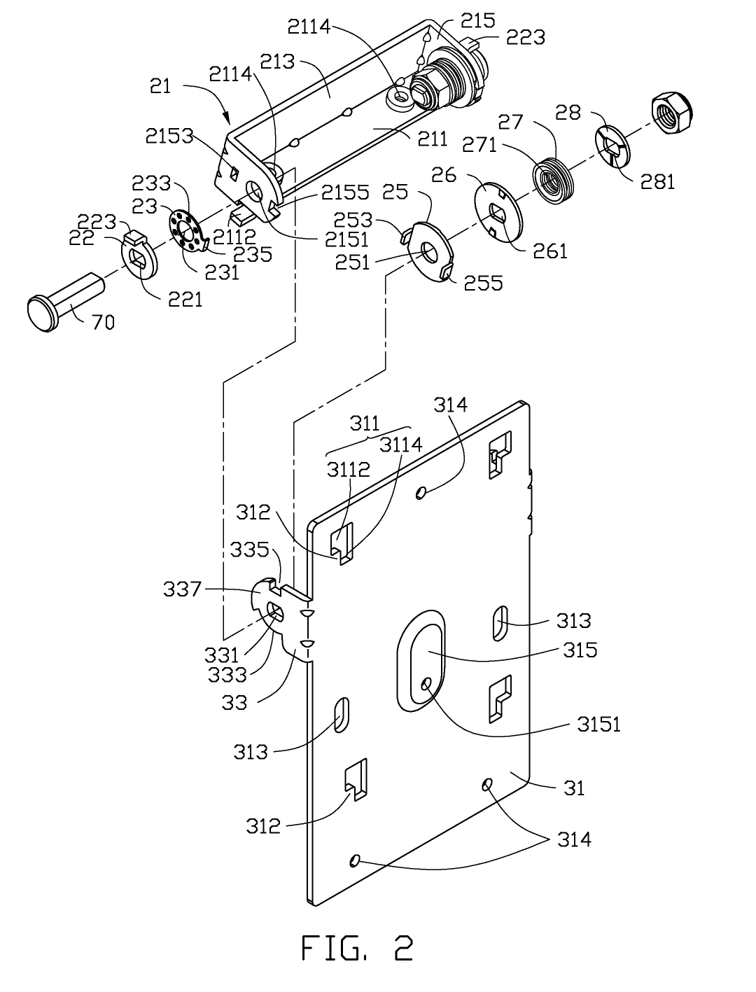

Referring to FIGS. 1 and 2, an adjustable apparatus, in accordance with an embodiment, includes a support 10, a hinge 20 secured to the support 10, and a mounting member 30 secured to the hinge 20. In one embodiment, the mounting member 30 is used to secure an enclosure 40 of an all-in-one computer. The enclosure 40 for example can be, used to secure a motherboard, a power, a fan, or a display.

A panel 11 extends from the inner surface of the support 10, and a base 13 is disposed on the bottom of the support 10. A pair of securing holes 112 is defined in the panel 11. The base 13 may be placed on the floor or a supporting place. In one embodiment, the support 10 is a rectangle.

The hinge 20 includes a tray 21, two engaging members 22, two wear washers 23 (only one is shown), a number of resistance washers 25, 26, and a number of rubber washers 27, 28. The tray 21 includes a mounting panel 211, a connecting panel 213 connected to the mounting panel 211, and two side panels 215 connected to the mounting panel 211 and the connecting panel 213. Two blocks 2112 extend from two opposite edges of the mounting panel 211 outside of the side panels 215. Two mounting holes 2114 are defined in the mounting panel 211, corresponding to the two securing holes 112 of the support 10.

A though hole 2151, a clipping hole 2153, and a notch 2155 are defined in each side panel 215. In one embodiment, the through hole 2151 is located between the clipping hole 2153 and the notch 2155. The engaging members 22, the wear washers 23, the resistance washers 25, 26, and the rubber washers 27, 28 are used to offer friction. A number of fixing holes 221, 231, 251, 261, 271, 281 are respectively defined in the engaging members 22, the wear washers 23, the resistance washers 25, 26, and the rubber washers 27, 28, corresponding to the through hole 2151. A catch 223 is disposed on the edge of the engaging member 22. A number of openings 233 are defined in the wear washer 23, for lubricant to flow into the wear washer 23. A positioning portion 235 is disposed on the edge of the wear washer 23, corresponding to the notch 2155 of the side panel 215. Two fastening pieces 253, 255 are located on each resistance wear 25, corresponding to the clipping hole 2153 and the notch 2155 of the side panel 215. In one embodiment, the two fastening pieces 253, 255 are substantially perpendicular to each other.

The mounting member 30 includes a main body 31 and two pivot pieces 33 disposed on two opposite edges of the main body 31. Four positioning slots 311, a pair of sliding slots 313, and three fixing holes 314 are defined in the main body 31. In one embodiment, the four positioning slots 311 are arranged in four corners of a rectangle area. Each positioning slot 311 includes a first portion 3112 and a second portion 3114 communicating to the first portion 3112, and the second portion 3114 has and less diameter than that of the first portion 3112. A stopper portion 312 is located on the main body 31, is directly connected to the positioning slot 311. An accommodating portion 315 protrudes from the center of the main body 31, and a fixing hole 3151 is defined in the accommodating portion 315.

A pivot hole 331 is defined in the pivot piece 33, corresponding to the through hole 2151 of the side panel 215. A cambered surface 333 is disposed on one side of the pivot piece 33, and an indentation 335 is defined in an opposite side of the pivot piece 33, corresponding to the catch 223 of the engaging member 22.

A hole 41 is defined in the enclosure 40, for the pivot piece 33 passing through. Four retaining portions 43, two posts 45 inserted into the two sliding slots 313, a protrusion 46 accommodated in the accommodating portion 315 are disposed on the inner surface of the enclosure 40. Each retaining portion 43 includes a jointing piece 431 and three ribs 435 arranged one side of the jointing piece 431. In one embodiment, the jointing piece 431 is L-shaped, and a space 436 is defined in the jointing piece 431. A screw hole 461 is defined in the protrusion 46, corresponding to the fixing hole 3151 of the accommodating portion 315. Three screw holes 47 are defined in the enclosure 40, corresponding to the three fixing holes 314 of the main body 31.

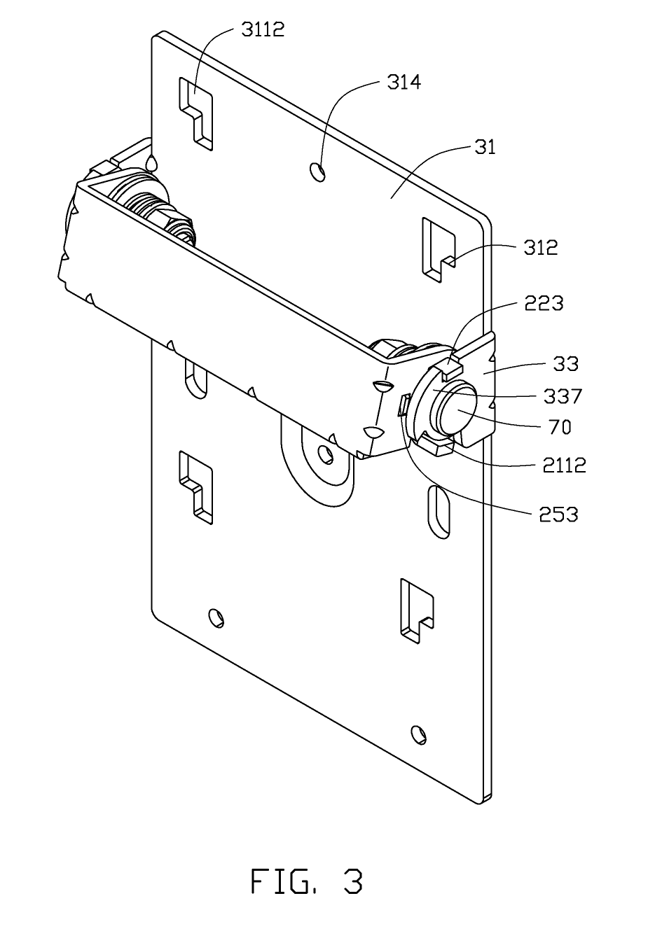

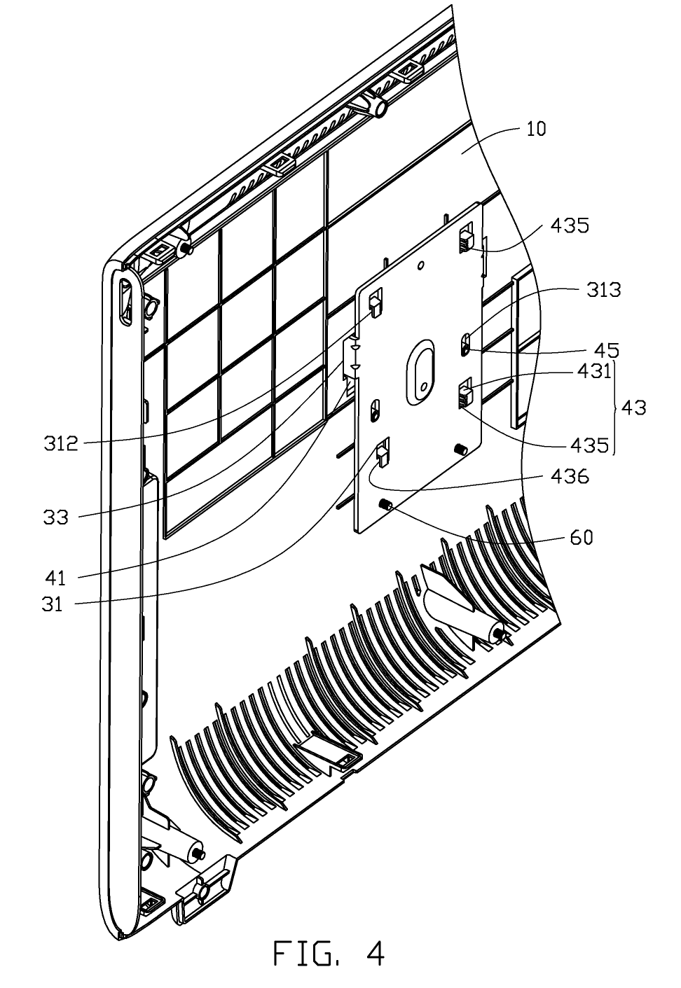

Referring to FIGS. 3-4, in assembly, the pivot piece 33 of the mounting member 30 passes through the hole 41, from the inside to the outside of the enclosure 40, and is located on the bottom of the hole 41. The retaining portion 43 is accommodated in the first portion 3112 of the positioning slot 311, and the ribs 435 of the retaining portion 43 abut the edge of the positioning slot 311. The post 45 is located an upper end of the sliding slot 313, and the protrusion 46 is received in an upper end of the accommodating portion 315. The mounting member 30 is pulled upwards, and the pivot piece 33 is slid upwards in the hole 41 until the retaining portion 43 is accommodated in the second portion 3114 of the positioning slot 311; the ribs 435 of the retaining portion 43 abut the edge of the second portion 3114, the post 45 is located a lower end of the sliding slot 313; and the protrusion 46 is received in a lower end of the accommodating portion 315. Therefore, the stopper portion 312 is engaged in the space 436 of the enclosure 40, and the post 45 is located at a down end of the sliding slot 313. The protrusion 46 is located at a down end of the accommodating portion 315. The four fixing holes 314, 3151 are aligned with the four screw holes 47, 461. Four fixing members 60 are inserted into the four fixing holes 314, 3151 and the four screw holes 47, 48, to secure the mounting member 30 to the enclosure 40.

Each wear washer 23 abuts the outside of each side panel 215, and the positioning portion 235 of the wear washer 23 is engaged in the notch 2155. Each engaging member 22 abuts each wear washer 23. Each pivot piece 33 abuts the engaging member 22, the catch 223 of the engaging member 22 is positioned in the indentation 335, and the block 2112 of the hinge 20 abuts the cambered surface 333. Each resistance washer 25 abuts inside of each side panel 215 of the hinge 20, and the two fastening pieces 253, 255 are inserted into the clipping hole 2153 and the notch 2155. The resistance washer 26 and the rubber washers 27, 28 in turn abut the resistance washer 25. The fixing holes 221, 231, 251, 261, 271, 281 are aligned with the through hole 2151 of the side panel 215 and the pivot hole 331, a fastening component 70 is screwed into the fixing holes 221, 231, 251, 261, 271, 281, the through hole 2151, and the pivot hole 331, and the mounting member 30 is thus secured to the hinge 20. The pivot piece 33 can be rotated between a first position and a second position. In the first position, the positioning portion 2112 of the hinge 20 is located in a first end of the cambered surface 333 of the mounting member 30, and a first acute angle is formed between the connecting panel 213 of the hinge 20 and the main body 31. In the second position, the positioning portion 2112 of the hinge 20 is located in a first end of the cambered surface 333 of the mounting member 30, and a second acute angle less than that of the first acute angle is formed between the connecting panel 213 and the main body 31.

The mounting panel 211 of the hinge 20 is placed on the panel 11. The mounting holes 2114 of the mounting panel 211 are aligned with the securing holes 112 of the panel 11. Two securing components 50 are inserted into the mounting holes 2114 and the securing holes 112, and the hinge 20 is thus secured to the support 10.

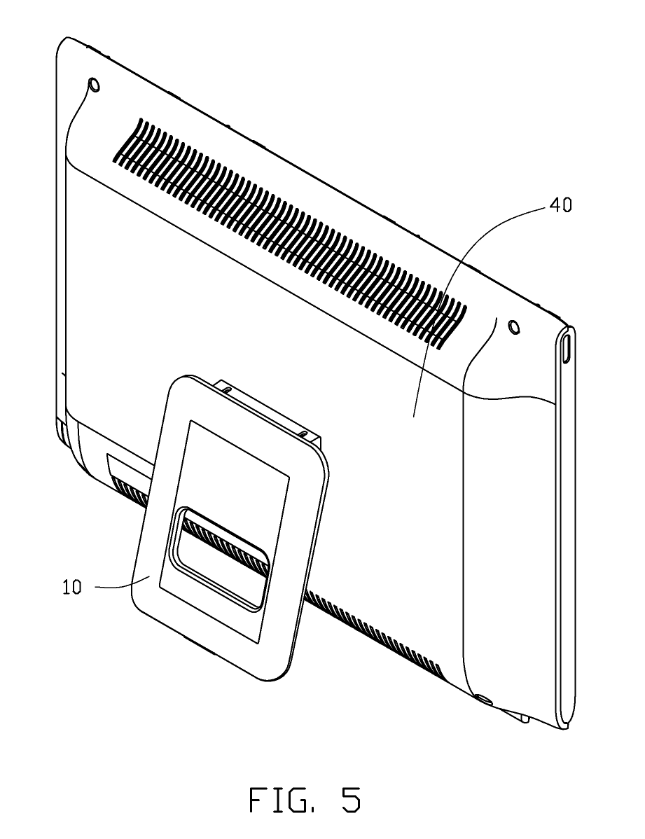

Referring to FIG. 5, when the viewing angle of the display (not shown) secured the enclosure 40 needs to be adjusted, the mounting member 30 can be rotated and positioned in any position between the first and second positions. The engaging members 22, the wear washers 23, the resistance washers 25, 26, and the rubber washers 27, 28 produce friction on the fastening component 70 and the pivot pieces 33.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An adjustable apparatus comprising:
an enclosure configured for securing a display, a hole defined in the enclosure;
a support located on a ground;
a hinge comprising a mounting panel, secured to the support, and a side panel, connected to the mounting panel; and
a mounting member comprising a main body and a pivot piece connected to the main body;
wherein the main body of the mounting member is attached to an inside of the enclosure, and the pivot piece is passed through the enclosure through the hole and rotatably engaged with the side panel of the hinge.

2. The adjustable apparatus of claim 1, wherein a space is defined in the enclosure, a stopper portion is located in the main body, and the stopper portion is engaged in the space.

3. The adjustable apparatus of claim 2, wherein a positioning slot is defined in the main body, and the stopper portion is connected to the positioning slot.

4. The adjustable apparatus of claim 2, wherein a retaining portion is located on the inside of the enclosure, the retaining portion comprises a jointing piece, and the space is defined in the jointing piece.

5. The adjustable apparatus of claim 4, wherein the retaining portion further comprises a rib disposed on a side of the jointing piece, and the rib abuts an edge of the positioning slot.

6. The adjustable apparatus of claim 1, wherein a sliding slot is defined in the main body, and a post protrudes on the inside of the enclosure and is engaged in the sliding slot.

7. The adjustable apparatus of claim 1, wherein a block extends from the hinge, and a cambered surface, engaged with the block, is disposed on the pivot piece.

8. The adjustable apparatus of claim 1, wherein a number of washers are secured to the side panel.

9. An adjustable apparatus comprising:
an enclosure configured for securing a display;
a support located on a ground;
a hinge secured to the support, comprising a connecting panel and a mounting panel, and a block extending from the mounting panel; and
a mounting member comprising a main body secured to the enclosure and a pivot piece connected to the main body, and a cambered surface defined in the pivot piece;
wherein the pivot piece abuts the block, and the block is configured to rotate between a first position and a second position, in the first position, the block is located in a first end of the cambered surface, and a first acute angle is formed between the connecting panel and the main body; in the second position, the block is located in a second end of the cambered surface, and a second acute angle less than that of the first acute angle is formed between the connecting panel and the main body.

10. The adjustable apparatus of claim 9, wherein a hole is defined in the enclosure, and the pivot piece is passed through the enclosure though the hole.

11. The adjustable apparatus of claim 9, wherein a space is defined in the enclosure, a stopper portion is located in the main body, and the stopper portion is engaged into the space.

12. The adjustable apparatus of claim 11, wherein a positioning slot is defined in the main body, and the stopper portion is connected to the positioning slot.

13. The adjustable apparatus of claim 11, wherein a retaining portion is located the inside of the enclosure, the retaining portion comprises a jointing piece, and the space is defined in the joint piece.

14. The adjustable apparatus of claim 13, wherein the retaining portion further comprises a rib disposed on a side of the jointing piece, and the rib abuts an edge of the positioning slot.

15. The adjustable apparatus of claim 9, wherein a sliding slot is defined in the main body, and a post protrudes on the inside of the enclosure and engaged into the sliding slot.

16. The adjustable apparatus of claim 9, wherein the hinge comprises two side panels connected to opposite edges of the mounting panel, and a number of washers is secured to each side panel.
